(19) United States
(12) Patent Application Publication
(10) Pub. No.: US 2017/0047202 A1
(43) Pub. Date: Feb. 16, 2017

(54) MAGNETIZED EDGE RING FOR EXTREME EDGE CONTROL

(71) Applicant: Lam Research Corporation, Fremont, CA (US)

(72) Inventor: Prashanth Kumar, Fremont, CA (US)

(21) Appl. No.: 14/823,977

(22) Filed: Aug. 11, 2015

(51) Int. Cl. H01J 37/32; H01L 21/67

(52) U.S. Cl. CPC H01J 37/32339; H01J 37/32082; H01J 37/3244; H01J 37/32449; H01L 21/67069

(57) ABSTRACT

An apparatus, for treating a substrate in a plasma processing chamber with an electromagnet power source with leads. An edge ring body surrounds the substrate. An electromagnet is embedded within or attached to a surface of the edge ring body, extending more than half way around the edge ring, wherein the electromagnet is configured to provide a magnetic flux greater than 0.1 mTesla along more than half of an outer edge of the substrate, wherein the electromagnet comprises at least one winding, wherein the leads of the electromagnet power source are electrically connected to the at least one winding.

### BACKGROUND

This disclosure relates to the manufacturing of semiconductor devices. More specifically, the disclosure relates to the manufacturing of semiconductor devices in a plasma processing chamber.

Control of the plasma sheath and ion trajectory at the extreme edge is dictated by the mechanical design of the edge ring. The profile in this region, over which part of the wafer hangs, is sloped. It is variation in this slope that allows for control of uniformity at the extreme edge. However, the change in slope can only be used to control uniformity for a limited number of processes. Moreover, a significant drawback is that the edge ring has to be changed every time the process regime shifts, in order to provide for a different slope.

### SUMMARY

Disclosed herein are various embodiments, including an apparatus, for treating a substrate in a plasma processing chamber with an electromagnet power source with leads. An edge ring body surrounds the substrate. An electromagnet is embedded within or attached to a surface of the edge ring body, extending more than half way around the edge ring, wherein the electromagnet is configured to provide a magnetic flux greater than 0.1 mTesla along more than half of an outer edge of the substrate, wherein the electromagnet comprises at least one winding, wherein the leads of the electromagnet power source are electrically connected to the at least one winding.

In another manifestation, plasma processing chamber for processing a substrate with an area is provided. A processing chamber is provided. A substrate support supports the substrate within the processing chamber. A gas inlet provides gas into the processing chamber above a surface of the substrate. An edge ring surrounds the substrate support. An electromagnet power source is provided. An electromagnet is incorporated in the substrate support or edge ring configured to provide a magnetic flux greater than 0.1 mTesla along more than half of an outer edge of the substrate, wherein the electromagnet encloses an area of at least half of the area of the substrate and comprises at least one winding and a pair of leads electrically connected to the electromagnet power source.

In another manifestation, an apparatus for treating a substrate on a substrate support in a plasma processing chamber is provided. A toroidal electromagnet is provided within the plasma processing chamber and configured to provide a toroidal magnetic flux greater than 0.1 mTesla at an outer edge of the substrate.

These and other features of the present inventions will be described in more detail below in the detailed description and in conjunction with the following figures.

### BRIEF DESCRIPTION OF THE DRAWINGS

The disclosed inventions are illustrated by way of example, and not by way of limitation, in the figures of the accompanying drawings and in which like reference numerals refer to similar elements and in which:

FIG. 1 schematically illustrates a cross-sectional view of an example of a plasma processing chamber which may be used in an embodiment.

FIG. 2A is an enlarged bottom view of the edge ring.

FIG. 2B is an enlarged section of the electromagnet in FIG. 2A.

FIG. 3A is an enlarged bottom view of the edge ring in another embodiment.

FIG. 3B is an enlarged section of the electromagnet in FIG. 3A.

FIG. 4A is an enlarged bottom view of the edge ring in another embodiment.

FIG. 4B is a cross-sectional view of the electromagnet in FIG. 4A.

### DETAILED DESCRIPTION

Inventions will now be described in detail with reference to a few of the embodiments thereof as illustrated in the accompanying drawings. In the following description, specific details are set forth in order to provide a thorough understanding of the present invention. However, the present invention may be practiced without some or all of these specific details, and the disclosure encompasses modifications which may be made in accordance with the knowledge generally available within this field of technology. Well-known process steps and/or structures have not been described in detail in order to not unnecessarily obscure the present disclosure.

Growth in the semiconductor industry is driven by advances in plasma processing and design of chamber hardware. Device manufacturers want to maximize the yield and efficiently utilize the real estate available on the substrate. This is most challenging at the extreme edge of the wafer which, in most commonly used designs in the industry, is not in contact with the ESC. This part of the wafer hangs over what is known as the edge ring. This edge ring is electrically isolated from both the ESC and the wafer. Maintaining uniformity in this region is dictated by a plurality of factors that are dependent on the regime used for processing the substrate. However, control of uniformity and plasma at this extreme edge is currently only possible by altering the mechanical design of the edge ring, i.e., a new edge ring is potentially required for different process regimes. This document describes a technology where-in magnetic fields are provided by means of wires, embedded in the edge ring, at the very edge of the wafer. By controlling the currents in the electromagnets one could potentially obtain arbitrary magnetic field configurations. This in turn allows control of the plasma sheath and ion trajectory at the very edge providing finer control at the extreme edge without need to change the edge ring for various processes.

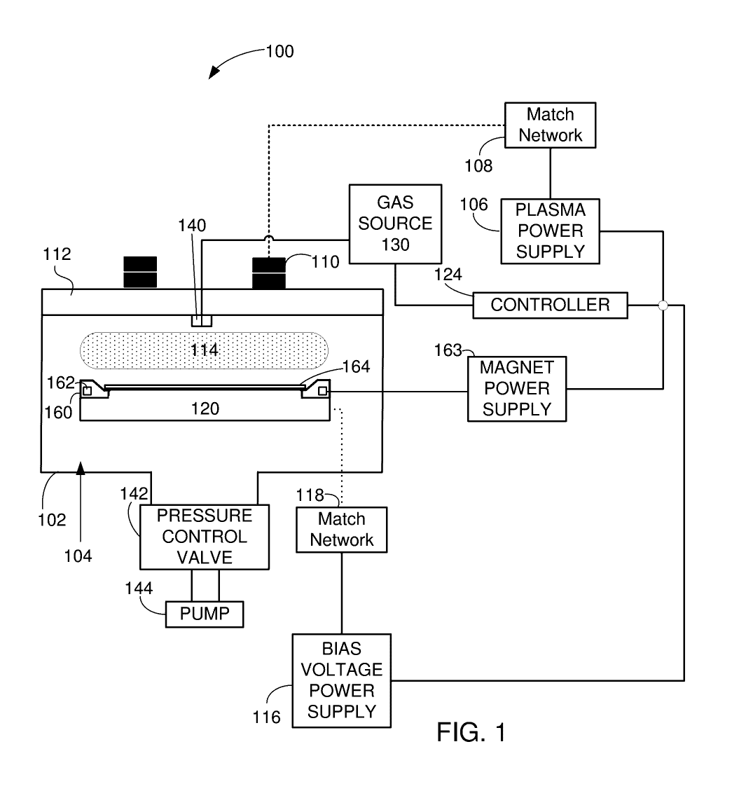

To facilitate understanding, FIG. 1 schematically illustrates a cross-sectional view of an example of a plasma processing chamber 100 which may be used in an embodiment. The plasma processing chamber 100 includes a plasma reactor 102 having a plasma processing confinement chamber 104 therein. A plasma power supply 106, tuned by a match network 108, supplies power to a TCP coil 110 located near a power window 112 to create a plasma 114 in the plasma processing confinement chamber 104 by providing an inductively coupled power. The TCP coil (upper power source) 110 may be configured to produce a uniform diffusion profile within the plasma processing confinement chamber 104. For example, the TCP coil 110 may be configured to generate a toroidal power distribution in the plasma 114. The power window 112 is provided to separate the TCP coil 110 from the plasma processing confinement chamber 104 while allowing energy to pass from the TCP coil 110 to the plasma processing confinement chamber 104. A wafer bias voltage power supply 116 tuned by a match network 118 provides power to an electrode 120 to set the bias voltage on the substrate 164 which is supported by the electrode 120. A controller 124 sets points for the plasma power supply 106, gas source/gas supply mechanism 130, and the wafer bias voltage power supply 116.

The plasma power supply 106 and the wafer bias voltage power supply 116 may be configured to operate at specific radio frequencies such as, for example, 13.56 MHz, 27 MHz, 2 MHz, 60 MHz, 400 kHz, 2.54 GHz, or combinations thereof. Plasma power supply 106 and wafer bias voltage power supply 116 may be appropriately sized to supply a range of powers in order to achieve desired process performance. For example, in one embodiment of the present invention, the plasma power supply 106 may supply the power in a range of 50 to 5000 Watts, and the wafer bias voltage power supply 116 may supply a bias voltage in a range of 20 to 2000 V. In addition, the TCP coil 110 and/or the electrode 120 may be comprised of two or more sub-coils or sub-electrodes, which may be powered by a single power supply or powered by multiple power supplies.

As shown in FIG. 1, the plasma processing chamber 100 further includes a gas source/gas supply mechanism 130. The gas source 130 is in fluid connection with plasma processing confinement chamber 104 through a gas inlet, such as a gas injector 140. The gas injector 140 may be located in any advantageous location in the plasma processing confinement chamber 104, and may take any form for injecting gas. Preferably, however, the gas inlet may be configured to produce a “tunable” gas injection profile, which allows independent adjustment of the respective flow of the gases to multiple zones in the plasma process confinement chamber 104. The process gases and byproducts are removed from the plasma process confinement chamber 104 via a pressure control valve 142 and a pump 144, which also serve to maintain a particular pressure within the plasma processing confinement chamber 104. The pressure control valve 142 can maintain a pressure of less than 1 Torr during processing. An edge ring 160 is placed around the wafer 164. The gas source/gas supply mechanism 130 is controlled by the controller 124. A Kiyo by Lam Research Corp. of Fremont, Calif., may be used to practice an embodiment. In this embodiment, an electromagnet 162 is placed around a circumference of the edge ring 160. In this example the electromagnet is not placed outside and around an outer circumference of the edge ring 160, but is placed around an inner circumference of the edge ring 160. An electromagnet power source 163 is electrically connected to the electromagnet 162 and is controllably connected to the controller 124.

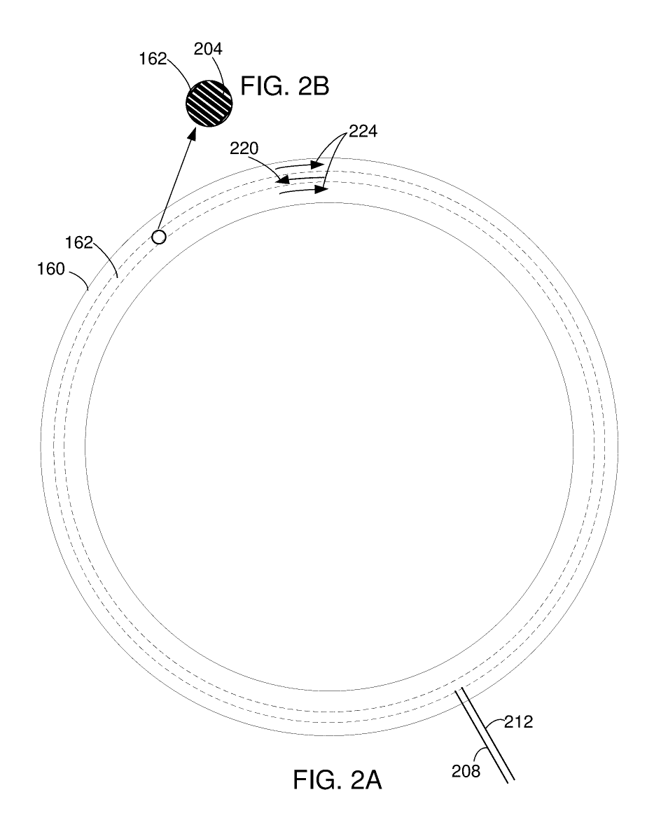

FIG. 2A is an enlarged bottom view of the edge ring 160. The electromagnet 162 is embedded in the edge ring 160 or edge ring body, and therefore is shown in dashed lines. FIG. 2B is an enlarged section of the electromagnet 162. In this embodiment, the electromagnet has a plurality of windings 204, substantially radial to the ring formed by the electromagnet 162 in order to form a solenoid ring. A first lead 208 and a second lead 212 are used to transmit power from the electromagnet power supply. The electromagnet 162 would provide a magnetic field indicated by arrow 220 in a direction around the circumference of the electromagnet 162 in the center of the electromagnet and magnetic fields indicated by arrows 224 in the opposite direction outside of the electromagnet 162. This is a toroidal magnetic field. The electromagnet 162 is in the form of a solenoid ring, with a solenoid axis at the center of the solenoid extending around the circumference of the electromagnet. Arrow 162 may also be used to indicate the solenoid axis. Since the solenoid ring forms a toroidal magnetic field, it is also a toroidal electromagnet. If the electromagnet power supply provides a DC voltage, the magnetic fields stay in the same direction. If the electromagnet power supply provides an AC voltage, the magnetic fields will constantly reverse directions. The magnetic fields 224 may be used to change plasma confinement properties near the edge ring 160. By changing the voltage provided by the electromagnet power supply, the confinement properties may be altered and tuned.

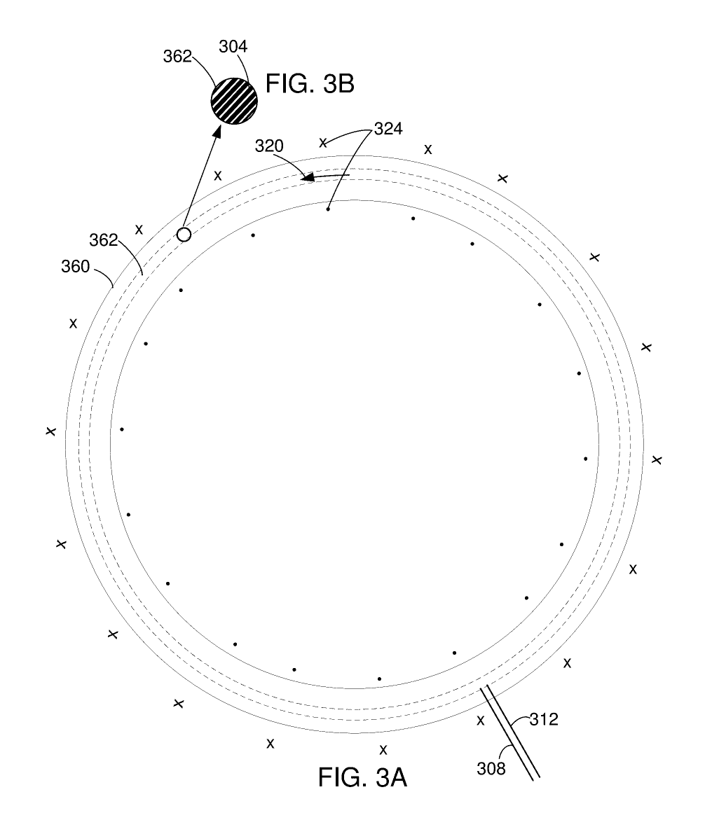

FIG. 3A is an enlarged bottom view of the edge ring 360 in another embodiment. The electromagnet 362 is embedded, and therefore is shown in dashed lines. FIG. 3B is an enlarged section of the electromagnet 362. In this embodiment, the electromagnet has a plurality of windings 304, substantially parallel to the circumference of the ring formed by the electromagnet 362 in order to form a coil ring. A first lead 308 and a second lead 312 are used to transmit power from the electromagnet power supply. If current is provided in the winding 304 in the direction as indicated by arrow 320, then according to the right hand rule a magnetic filed 324 would be created, where the magnetic field 324 goes into the page on the outside of the edge ring 360 and comes out of the page inside the edge ring 360, as shown. This is a poloidal magnetic field, so that the coil ring is a poloidal electromagnet. The magnetic field 324 may be used to change plasma confinement properties near the edge ring 360. By changing the voltage provided by the electromagnet power supply, the confinement properties may be altered and tuned.

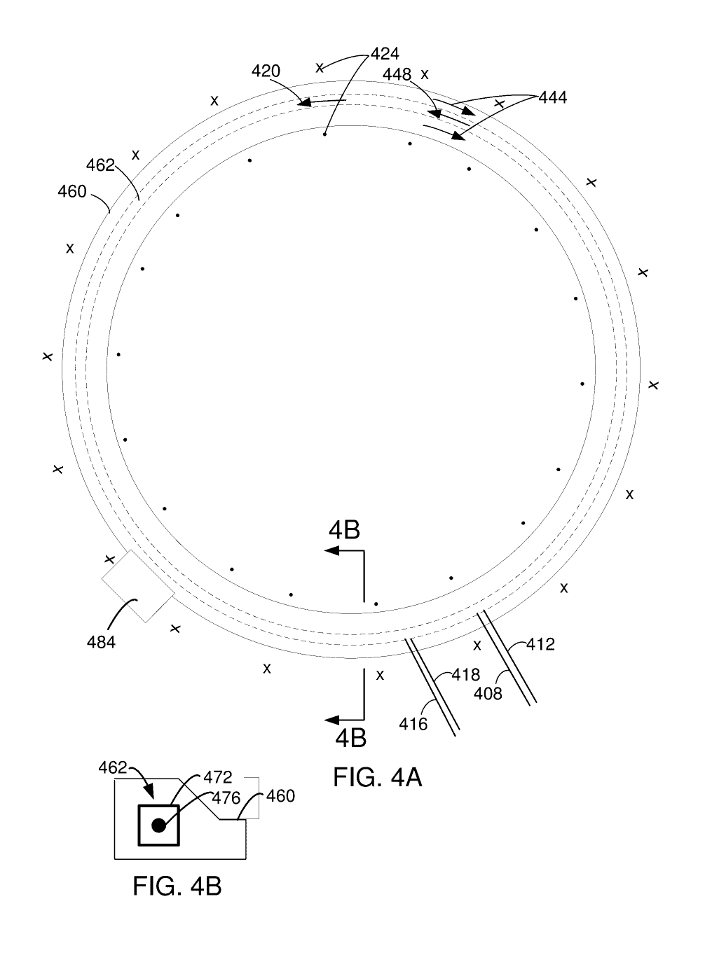

FIG. 4A is an enlarged bottom view of the edge ring 460 in another embodiment. The electromagnet 462 is embedded, and therefore is shown in dashed lines. FIG. 4B is a cross-sectional view of the edge ring 460 along cut lines 4B. In this embodiment, the electromagnet 462 is a combination of a solenoid electromagnet 472 surrounding a coil ring electromagnet 476 so that the windings of the coil ring electromagnet 476 extend along the solenoid axis of the solenoid electromagnet 472. A first lead 408 and a second lead 412 are used to transmit power from the electromagnet power supply to the solenoid electromagnet 472. A third lead 416 and a fourth lead 418 are used to transmit power from the electromagnet power supply to the coil ring electromagnet 476. If current is provided in the coil ring electromagnet 476 in the direction as indicated by arrow 420, then according to the right hand rule a magnetic field 424 would be created, where the magnetic field 424 goes into the page on the outside of the edge ring 460 and comes out of the page inside the edge ring 460, as shown. This is a poloidal magnetic field. Current in the solenoid electromagnet 472 would provide a magnetic field 448 in a direction around the circumference of the solenoid electromagnet 472 in the center of the solenoid electromagnet 472 and magnetic fields 444 in the opposite direction outside of the solenoid electromagnet 472. The electromagnet 462 is a toroidal electromagnet and a poloidal electromagnet. The use of two different types of electromagnets provides twice as many tuning controls than when only one type of electromagnet is provided. A heater element 484 may be attached to or embedded in the edge ring 460. Such a heater element is directly attached to the controller or indirectly attached to the controller through a heater controller. The heater element 484 may be used to thermally tune the edge ring 460.

By supplying current to the wires, poloidal and toroidal magnetic fields are generated. The strength of these fields is directly a function of the supplied current, wire geometry and surrounding dielectric medium. Of course the amount of current supplied to both wires can be different. In doing so, one can, by the superposition principle in electromagnetic theory, generate arbitrary field configurations that extend into the space beyond the edge ring. Since a plasma follows the magnetic field lines, the ion path follows the field configuration. This allows for control of the shape of the sheath of the plasma at the very edge. One notes that various sheath profiles can be obtained by simply changing the currents in the wires without the need to replace the edge ring.

The edge ring may also containing circuitry for filtering the RF supplied to generate the plasma. This filter may be internal (embedded in the edge ring) or external. This is important so as to ensure that the field lines are not disrupted by extraneous currents which could change the intended plasma sheath profile. The filter may be simple containing only passive RLC (resistive, inductive, and capacitive) components, which would include cascaded versions, or may contain active components such as transistors and diodes.

Other embodiments may also use a permanent magnet for the edge ring material, but such permanent magnets would not provide adjustable or tunable magnetic fields.

Some advantages provided by some embodiments may include, but may not be limited to the following: Potential low cost: Compared to using different edge rings with different slopes for various processes, the above outlined technology provides a potentially cheaper alternative by allowing change in the extreme edge uniformity by simply changing the currents in the wires. Applicability to all processes: The technology is applicable to dielectric and conductor processes. Further it can be implemented on legacy systems. Finer control of extreme edge profile: Due to ability to control the magnetic field through currents, it is possible to obtain more granularity in control of uniformity and profile at the extreme edge of the wafer.

AC power can also be supplied to the electromagnets. The frequency of AC should be at least 0.01 Hz. AC clamping requires redesign of the edge ring, which are not backward compatible with existing edge ring technology. AC clamping requires providing high current and filtering circuitry to power the wires in the edge ring.

If a wafer is subjected to many different processes the current in the electromagnet may be varied for each different process. A purely mechanical edge ring would not be so adjustable. An embodiment may program the controller 124 to have different steps, so that each different process step may provide different process gases, different plasma powers and different electromagnet powers.

Preferably, an electromagnet extends at least half way around the circumference of the edge ring. Most preferably, an electromagnet extends at least completely around the circumference of the edge ring. Preferably, an electromagnet has an electrical resistivity of less than 10⁻⁴ ohm-m at 20° C. Preferably, the electromagnet produces a magnetic flux density of at least 0.1 mT at the outer edge of the substrate. In this embodiment, since the electromagnet is adjacent to the entire outer edge of the substrate, the electromagnet produces a magnetic flux density of at least 0.1 mT at the entire outer edge of the substrate. In other embodiments, the electromagnet produces a magnetic flux density of at least 0.1 mT for more than half of the outer edge of the substrate. More preferably the electromagnet produces a magnetic flux density of between 10⁻¹ mT and 10³ mT at the outer edge of the substrate. If the resistance of the electromagnet is too high, the current in the electromagnet would bet too low, which would cause a magnetic field of less than 0.1 mT, which would not provide a significant improvement in confinement.

In some embodiments, the power is inductively coupled to the plasma. In other embodiments, the power is capacitive coupled to the plasma. In some embodiments the edge ring may be hollow. In other embodiments the edge ring may be solid. In other embodiments the edge ring may be hollow and filled with a dielectric material to optimize magnetic field density. In various embodiments, the edge rings may be made of various dielectric materials, such as, silicon, silicon nitride, or silicon carbide. In various embodiments, the edge rings may be of an isolative ceramic material. In other embodiments, instead of being embedded in an edge ring, the electromagnets may be bound to a surface of an edge ring. However, if the electromagnets are on a surface of an edge ring, the electromagnets may need additional shielding for protection from RF power and from etching conditions. An advantage of having electromagnets within the edge ring helps control polymer accumulation near the edge of a wafer. Embodiments may also use the controller to provide a feedback loop to further tune the electromagnets.

In some embodiments the substrate has a larger diameter than the substrate support, so that the outer edges of the substrate extend over the edge ring. In order to provide a magnetic flux density of at least 0.1 mTesla at the edge of the substrate, in one embodiment the electromagnet is located between 10% inside the substrate diameter and 10% outside the substrate diameter. In such embodiments, the electromagnet may have a diameter equal to between 90% to 110% of the diameter of the substrate. For example, if the substrate has a 300 mm diameter, the electromagnet would have a diameter between 270 mm and 330 mm and the center of the electromagnet would align with the center of the substrate. As a result the electromagnet forms a ring with an inner area that is at least half of the area of the substrate. Since the substrate support has a diameter that is less than the diameter of the substrate, the diameter of the electromagnet would be between 90% and 110% of the diameter of the substrate support. In an embodiment, the electromagnet only tunes confinement at the edge of the substrate. Therefore, in such an embodiment the magnetic field from the electromagnet significantly drops towards the center of the substrate. For example, the magnetic flux may drop more than 80% between the edge of the substrate and half the distance to the center of the substrate.

Embodiments that provide a toroidal electromagnet may provide a toroidal magnetic field less half the outer edge of the substrate.

While inventions have been described in terms of several preferred embodiments, there are alterations, permutations, and various substitute equivalents, which fall within the scope of this invention. There are many alternative ways of implementing the methods and apparatuses disclosed herein. It is therefore intended that the following appended claims be interpreted as including all such alterations, permutations, and various substitute equivalents as fall within the true spirit and scope of the present invention.

What is claimed is:

1. An apparatus, for treating a substrate in a plasma processing chamber with an electromagnet power source with leads, comprising:
an edge ring body surrounding the substrate; and
an electromagnet embedded within or attached to a surface of the edge ring body, extending more than half way around the edge ring, wherein the electromagnet is configured to provide a magnetic flux greater than 0.1 mTesla along more than half of an outer edge of the substrate, wherein the electromagnet comprises at least one winding; wherein the leads of the electromagnet power source are electrically connected to the at least one winding.

2. The apparatus, as recited in claim 1, wherein the electromagnet is a toroidal electromagnet.

3. The apparatus, as recited in claim 1, wherein the electromagnet is a poloidal electromagnet.

4. The apparatus, as recited in claim 1, wherein the electromagnet comprises a toroidal electromagnet and a poloidal electromagnet.

5. The apparatus, as recited in claim 1, wherein the edge ring body has a circumference, and wherein the electromagnet extends around the circumference of the edge ring.

6. The apparatus, as recited in claim 1, wherein the electromagnet power source is a source of AC current.

7. The apparatus, as recited in claim 1, wherein the electrical resistivity of the electromagnet is less than 10⁻⁴ ohm-m at 20° C.

8. The apparatus, as recited in claim 1, wherein the electromagnet is located between 10% inside a substrate diameter to 10% outside the substrate diameter.

9. The apparatus, as recited in claim 1, further comprising:
a processing chamber surrounding the edge ring body;
a substrate support surrounded by the edge ring body for supporting the substrate within the processing chamber;
a gas source;
a plasma power source for forming a gas in the processing chamber into a plasma;
a gas inlet for providing gas from the gas source into the processing chamber above a surface of the substrate; and
an electromagnet power source electrically connected to the electromagnet.

10. The apparatus, as recited in claim 9, further comprising a controller electrically connected to the electromagnet power source, plasma power source, and the gas source, comprising:
at least one computer processing unit; and
computer readable media with computer readable code, comprising:
computer readable code for providing a first plasma power from the plasma power source, a first gas from the gas source; and a first electromagnet power; and
computer readable code for providing a second plasma power from the plasma power source, a second gas from the gas source, and a second electromagnet power, wherein the first gas is different from the second gas, the first plasma power is different than the second plasma power, and the first electromagnet power is different than the second electromagnet power.

11. A plasma processing chamber for processing a substrate with an area, comprising:
a processing chamber;
a substrate support for supporting the substrate within the processing chamber;
a gas inlet for providing gas into the processing chamber above a surface of the substrate;
an edge ring surrounding the substrate support;
an electromagnet power source; and
an electromagnet incorporated in the substrate support or edge ring configured to provide a magnetic flux greater than 0.1 mTesla along more than half of an outer edge of the substrate, wherein the electromagnet encloses an area of at least half of the area of the substrate and comprises:
a least one winding; and
a pair of leads electrically connected to the electromagnet power source.

12. The plasma processing chamber, as recited in claim 11, wherein the electromagnet forms a ring with a diameter wherein the substrate support has a diameter, and wherein a diameter of the electromagnet is between 90% to 110% of the diameter of the substrate support.

13. The plasma processing chamber, as recited in claim 12 wherein the electromagnet comprises a solenoid, with a solenoid axis which is extends around a circumference of the ring, wherein the solenoid creates a toroidal magnetic field at the outer edge of the substrate.

14. The plasma processing chamber, as recited in claim 13, wherein the electromagnet comprises a coil with a plurality of windings and a coil axis which is perpendicular to a surface of the substrate support, wherein the coil creates a poloidal magnetic field at the outer edge of the substrate.

15. An apparatus for treating a substrate on a substrate support in a plasma processing chamber, comprising a toroidal electromagnet within the plasma processing chamber, configured to provide a toroidal magnetic flux greater than 0.1 mTesla at an outer edge of the substrate.

16. The apparatus, as recited in claim 15, further comprising a poloidal electromagnet within the plasma processing chamber, configured to provide a poloidal magnetic flux greater than 0.1 mTesla at an outer edge of the substrate.

17. The apparatus, as recited in claim 15, wherein the toroidal electromagnet comprises a ring solenoid with a central axis in a ring shape to form a solenoid ring, and further comprising:
a processing chamber;
a substrate support for supporting the substrate within the processing chamber;
a gas source;
a plasma power source for forming a gas in the processing chamber into a plasma;
a gas inlet for providing gas from the gas source into the processing chamber above a surface of the substrate; and
an electromagnet power source electrically connected to the at least one toroidal electromagnet.
